(19) United States
(12) Patent Application Publication
(10) Pub. No.: US 2023/0163232 A1
(43) Pub. Date: May 25, 2023

(54) CHIP TRANSFER METHOD AND DISPLAY DEVICE

(71) Applicant: CHONGQING KONKA PHOTOELECTRIC TECHNOLOGY RESEARCH INSITUTE CO., LTD., Chongqing (CN)

(72) Inventor: Chen HUNG-WEN, Chongqing (CN)

(21) Appl. No.: 17/436,624

(22) PCT Filed: Aug. 12, 2020
(86) PCT No.: PCT/CN2020/108667

§ 371 Date: Sep. 6, 2021

(51) Int. Cl. H01L 33/00; H01L 27/15

(52) U.S. Cl. CPC H01L 33/005; H01L 27/156; H01L 2933/0008

(57) ABSTRACT

The application relates to a chip transfer method and a display device. The chip transfer method includes the following operations: providing a growth substrate; forming one or multiple chips on a surface of the growth substrate; and covering a first glue layer on a surface, away from the growth substrate, of the one or multiple chips; providing a first transient substrate covered with an uncured first thermosetting material layer; and attaching the first glue layer and the first thermosetting material layer; and curing the first thermosetting material layer so that an uneven surface of the first glue layer matches an uneven surface of the first thermosetting material layer to form a leveling layer.

### TECHNICAL FIELD

The application relates to the field of display technologies, and in particular, to a chip transfer method and a display device.

### BACKGROUND

Currently, a key technology faced by chip transfer technology is to transfer a chip to a display backplane via a mass transfer process. In a prior art, the chip is usually transferred to a first temporary substrate by adhesion with a degradable glue material, transferred from the first temporary substrate to a second temporary substrate by a similar method, then transferred from the second transient substrate to the backplane and bound to the backplane.

However, in a process of realizing chip transfer in the prior art, since a glue material coated on the temporary substrate has a fluid state before curing, there is often a difference in thickness of the glue material after curing. Therefore, during a pressure attaching transfer process with another substrate, due to a difference in a height of the glue material, the plurality of chips adheres under normal pressure, while the plurality of chips is incompletely adhered due to an insufficient height. The plurality of chips is trapped into the glue material on the surface of another temporary substrate due to too height, thereby causing the transfer to fail.

### SUMMARY

In view of the forgoing shortcomings of the prior art, an objective of this application is to provide a chip transfer method and a display device, aiming to solve a problem that the chip transfer method in a prior art easily causes part of chips to fail to transfer.

A chip transfer method includes the following operations of:

providing a growth substrate, forming one or multiple chips on a surface of the growth substrate, and covering a first glue layer on a surface, away from the growth substrate, of the one or multiple chips;

providing a first transient substrate covered with an uncured first thermosetting material layer; and attaching the first glue layer to the first thermosetting material layer; and

curing the first thermosetting material layer so that an uneven surface of the first glue layer is matched with an uneven surface of the first thermosetting material layer to form a leveling layer.

In the application, the first glue layer is covered on the surface of the one or multiple chips away from the growth substrate. The first glue layer is attached to the first thermosetting material layer covering the first transient substrate. Since the first thermosetting material is uncured and easy to deform, after attachment, a shape of the first thermosetting material corresponds to the heights and convexes of the first glue layer, thereby forming a complementary pattern and obtaining the leveling layer. Therefore, the one or multiple chips arranged thereon can be positioned on the same horizontal plane, and can realize effective attachment and adhesion under a proper attachment pressure. The first thermosetting material layer is cured after the attachment, thereby avoiding a problem that during a pressure attachment transfer process with another substrate, the one or multiple chips are incompletely attached or trapped into the glue material on a surface of another temporary substrate due to an insufficient height of the plurality of chips, thereby ensuring the successful transfer of the one or more chips.

In addition, with the forgoing chip transfer method of the present application, since the first thermosetting material layer corresponds to the first glue layer in heights and fluctuations in a complementary manner, the one or multiple chips can be on the same horizontal plane. Therefore, when the one or multiple chips are bonded with the display backplane, a problem of a bonding failure caused by different bonding pressures when the surfaces of electrodes in different heights correspond to different bonding pressures the one or multiple chips are at different levels because the surface of the chip is different in the level plane is avoided.

The first glue layer is formed by pyrolytic glue, and p a decomposition temperature of the pyrolytic glue is higher than a curing temperature of the first thermosetting material layer. By making the decomposition temperature of the pyrolytic glue be higher than the curing temperature of the first thermosetting material layer, it is ensured that the pyrolytic glue is not decomposed when the first thermosetting material layer is cured at a high temperature subsequently, thereby ensuring the adhesion to the one or multiple chips.

Optionally, the first glue layer is formed by photolytic glue. The first glue layer formed by the photolytic glue can be separated from the surface of the one or multiple chips by UV irradiation in a subsequent process, thereby achieving a simple process and high efficiency.

Optionally, the material of the first thermosetting material layer is one or multiple materials selected from phenolic resin, urea-formaldehyde resin, melamine resin, unsaturated polyester resin, epoxy resin, organic silicon resin, and polyurethane.

Optionally, there are multiple chips which are arranged at intervals. The operation of covering the first glue layer on the surface, away from the growth substrate, of the multiple chips includes: arranging a dead wall between adjacent chips, wherein a gap is provided between the chips and the dead wall; forming a soluble polymer layer on the growth substrate corresponding to the gap; and coating the first glue layer on the growth substrate, where the first glue layer is configured to cover the surface of, away from the growth substrate, of the one or multiple chips. By first forming the dead wall between the adjacent chips, each chip can be separated to avoid mutual influence. For example, when a chip A is lift offled off, but a chip B is not lift offled off, owing to the arrangement of the dead wall, the chip B can be prevented from being affected by laser irradiating chip A. Therefore, the chip B is not being affected when the chip A is lift offled off. Moreover, owing to the arrangement of the dead wall, after the dead wall is removed, a light-shielding structure can be formed at a removed position to prevent colors between the adjacent chips from being mixed.

Optionally, the height of the dead wall is the same as the height of the chips in a direction perpendicular to the growth substrate. The height of the dead wall is the same as the height of the chips, which not only makes a subsequently formed light-shielding structure have a sufficient height to prevent colors between adjacent chips from being mixed, but also can prevent the dead wall from being trapped in the first glue layer to make it difficult to lift off due to an excessive height.

Optionally, the height of the soluble polymer layer is less than the height of the dead wall in the direction perpendicular to the growth substrate. the height of the soluble polymer layer is less than the height of the dead wall, which can prevent the soluble polymers from crossing the dead wall and connecting two by two, prevent the adjacent chips from being affected during selective lifting, and prevent the soluble polymer layer from being too high to be trapped in the first glue layer to cause difficulty in lifting.

Optionally, the soluble polymer layer is a polyimide layer. The soluble polymer layer formed by polyimide can be quickly and effectively removed by an organic solvent such as N-methylpyrrolidone.

Optionally, after the operation of generating the leveling layer, the chip transfer method further includes: lifting the one or multiple chips from the growth substrate to transfer the one or multiple chips to the first transient substrate; and attaching the side of the first transient substrate with one or multiple chips to the second transient substrate via the second glue layer to transfer the one or multiple chips to the second transient substrate; and bonding the one or multiple chips on the second transient substrate to the display backplane to transfer the one or multiple chips to the display backplane.

Optionally, the operation of attaching the side of the first transient substrate with the one or multiple chips to the second transient substrate via the second glue layer includes: coating the second glue layer to the exposed side of the one or multiple chips on the first transient substrate; providing the second transient substrate having the surface covered with an uncured second thermosetting material layer, attaching the second thermosetting material layer to the second glue layer; curing the second thermosetting material layer; lifting off the one or multiple chips on the first transient substrate to transfer the one or multiple chips to the second transient substrate. The second glue layer and the second thermosetting material layer are used. Since the second thermosetting material is uncured and easily deformed, the shape of the second thermosetting material corresponds to the heights and convexes of the second glue layer after bonding, thereby forming a complementary pattern to further ensure that the chip can be positioned on the same horizontal level.

The second glue layer is formed by pyrolytic glue, and the decomposition temperature of the pyrolytic glue is higher than the curing temperature of the second thermosetting material layer. Since the decomposition temperature of pyrolytic glue is higher than the curing temperature of the second thermosetting material layer, it is ensured that pyrolytic glue is not decomposed when the second thermosetting material layer is cured at a high temperature subsequently, thereby ensuring the adhesion to the chip.

Optionally, the material of the second thermosetting material layer is one or more materials selected from phenolic resin, urea-formaldehyde resin, melamine resin, unsaturated polyester resin, epoxy resin, organic silicon resin, and polyurethane.

Optionally, after the operation of lifting off the one or multiple chips on the first transient substrate, the operation of transferring the one or multiple chips on the second transient substrate to the display backplane includes: forming the electrode on an exposed surface of each chip; providing the display backplane of which a surface has a contact pad; bonding the electrode of the chip on the second transient substrate to the contact pad; and lifting off the second transient substrate to transfer the chip to the display backplane.

Based on the same inventive concept, the application also provides a display device, including a display backplane and a chip located on the display backplane. The chip is transferred to the display backplane by using the chip transfer method as described above.

In the application, since the chip is transferred to the display backplane using the forgoing chip transfer method, the chip arranged thereon can be on the same horizontal level, avoids a problem that the plurality of chips may be incompletely bonded or trapped into an glue material on a surface of another transient substrate due to an insufficient height during a pressure attaching transfer process with another substrate, thereby ensuring a successful transfer of the chip, and ensuring luminous efficiency of the forgoing display device.

### BRIEF DESCRIPTION OF THE DRAWINGS

FIG. 1 is a schematic flowchart of a chip transfer method according to an embodiment of the application;

FIG. 2 is a schematic structural diagram of providing a growth substrate of which a surface is formed with one or multiple chips in a chip transfer method provided according to an embodiment of the application;

FIG. 3 is a schematic structural diagram after the one or multiple chips of which a side surface away from the growth substrate is covered with a first glue layer shown in FIG. 2;

FIG. 4 is a schematic structural diagram of providing a first transient substrate of which a surface is covered with a first thermosetting material layer and curing the first thermosetting material layer after attaching a first glue layer to the first thermosetting material layer shown in FIG. 3;

FIGS. 5 and 6 are schematic structural diagrams after the one or multiple chip on a growth substrate shown in FIG. 4 is lifted off by a laser lifting-off process;

FIG. 7 is a schematic structural diagram of providing a second transient substrate of which a surface is covered with a second thermosetting material layer and curing the second thermosetting material layer after attaching a second glue layer to the second thermosetting material layer shown in FIG. 5;

FIG. 8 is a schematic structural diagram after lifting off the one or multiple chips shown in FIG. 7 from a first glue layer;

FIG. 9 is a schematic structural diagram after forming an electrode on the exposed surface of the one or multiple chips shown in FIG. 8.

### THE DESCRIPTION OF REFERENCE SIGNS

10—growth substrate; 20—chip; 30—dead wall; 40—soluble polymer layer; 50—first glue layer; 60—first thermosetting material layer; 70—first transient substrate; 80—second glue layer; 90—second thermosetting material layer; 100—second transient substrate; 110—electrode.

### DETAILED DESCRIPTION OF THE EMBODIMENTS

In order to facilitate the understanding of the present disclosure, the following makes a more comprehensive description of the present disclosure with reference to the relevant drawings. Preferred embodiments of this application are shown in the drawings. However, the application can be implemented in many different forms and is not limited to the implementation described herein. On the contrary, an objective of providing these embodiments is to make the understanding of the disclosure of the present application more thorough and comprehensive.

Unless otherwise specified, all technical and scientific terms used herein have the same meaning as commonly understood by the person skilled in the art to which this application belongs. The terms used in the description of this application herein are only used for an objective of describing specific implementation, and are not intended to limit this application.

As described in the background, in the process of realizing chip transfer in a prior art, since a glue material coated on the temporary substrate has a fluid state before curing, there is often a difference in thickness of the glue material after curing. Therefore, during a pressure attaching transfer process with another substrate, the plurality of chips is incompletely adhered due to an insufficient height. The plurality of chips is trapped into the glue material on the surface of another temporary substrate due to too height, thereby causing the transfer to fail.

Based on this, the present application is intended to provide a solution that can solve the forgoing technical problems, the details of which is described in subsequent embodiments.

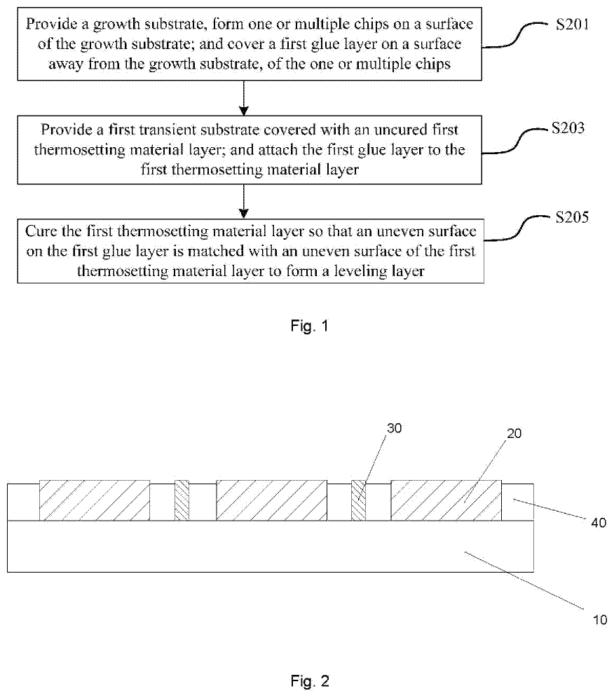

The inventor of this application conducted research for the forgoing problems and proposed a chip transfer method, as shown in FIG. 1.

Hereinafter, an exemplary implementation of the chip transfer method provided in the present application is described in more details with reference to the accompanying drawings. However, these exemplary embodiments can be implemented in a variety of different forms, and should not be construed as being limited to the embodiments set forth herein. It should be understood that these embodiments are provided to make the disclosure of this application thorough and complete, and to fully convey a concept of these exemplary embodiments to the person skilled in the art.

First, operation S201 is performed: providing a growth substrate 10, forming one or multiple chips 20 on a surface of the growth substrate 10, as shown in FIG. 2, and covering a first glue layer on a surface, away from the growth substrate, of the one or multiple chips. The forgoing growth substrate 10 may be a rigid substrate, such as a glass plate, a quartz plate, and a sapphire substrate.

In the forgoing operations, photolytic glue or pyrolytic glue may be coated on the growth substrate 10 to form the first glue layer 50 covering the one or multiple chips 20.

In some embodiments, the pyrolytic glue is used to form the first glue layer 50 covering the one or multiple chips 20. The decomposition temperature of the Pyrolytic glue is higher than the curing temperature of the first thermosetting material layer 60, thereby ensuring that the pyrolytic glue is not decomposed when the first thermosetting material layer is cured at a high temperature subsequently, and ensuring the adhesion to the one or multiple chips 20.

In some embodiments, a method of forming the forgoing chip 20 includes: completing a LED epitaxy film layer on the growth substrate 10 and cutting the LED epitaxy film layer to form a plurality of independent LED chips 20.

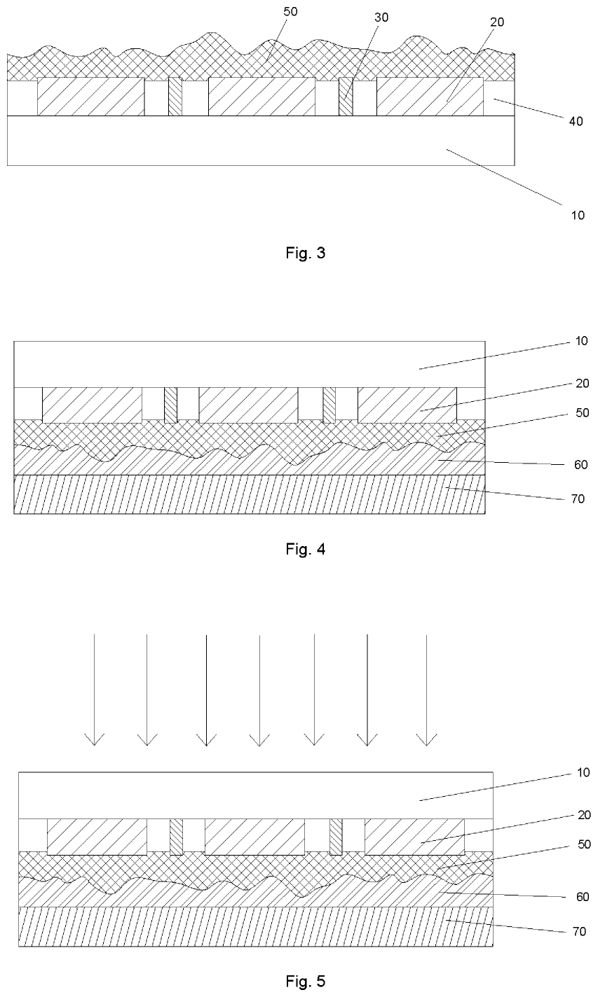

In some embodiments, the operation of covering the first glue layer 50 on the surface, away from the growth substrate 10, of the multiple chips 20 includes: arranging a dead wall 30 between adjacent chips 20, wherein a gap is provided between the chips 20 and the dead wall 30; forming a soluble polymer layer 40 on the growth substrate 10 corresponding to the gap, as shown in FIG. 2; and coating the first glue layer 50 on the growth substrate 10, wherein the first adhesive layer 50 also covers a surface of the dead wall 30 away from the growth substrate 10 and a surface of the soluble polymer layer 40 away from the growth substrate 10, as shown in FIG. 3.

In the forgoing embodiment, the soluble polymer layer 40 in the gap between the chip 20 and the dead wall 30 can be flattened, so that the first glue layer 50 coated on the growth substrate 10 has a better levelness, thereby reducing the unevenness of the surface of the first glue layer 50.

In the forgoing embodiment, the soluble polymer layer 40 may be a polyimide layer. However, the forgoing optional types are not limited. The person skilled in the art can reasonably select a type of the forgoing soluble polymer layer 40 according to the prior art. For example, the forgoing soluble polymer layer 40 may also serve as an acrylic organic layer.

In the forgoing embodiment, to avoid the difficulty of lifting caused by the dead wall 30 being trapped in the first glue layer 50 due to too high, preferably, the height of the dead wall 30 is the same as the height of the one or multiple chips 20 in a direction perpendicular to the growth substrate 10.

In the forgoing embodiment, to avoid the soluble polymer layer 40 being too high so as to be trapped in the first glue layer 50 and causing difficulty in lifting, preferably, the height of the soluble polymer layer is smaller than the height of the dead wall in the direction perpendicular to the growth substrate.

Then, operation S203 is performed: providing a first transient substrate 70 covered with the uncured first thermosetting material layer 60; and attaching the first glue layer 50 to the first thermosetting material layer 60; and

The forgoing first transient substrate 70 may be the rigid substrate, such as the glass plate, the quartz plate, and the sapphire substrate.

In the forgoing operation S203, the material of the first thermosetting material layer 60 can be one or multiple materials selected from phenolic resin, urea-formaldehyde resin, melamine resin, unsaturated polyester resin, epoxy resin, organic silicon resin, and polyurethane. However, the forgoing optional type is not limited. The person skilled in the art can reasonably select a type of the forgoing first thermosetting material layer 60 according to the prior art.

Then, operation S205 is performed: curing the first thermosetting material layer 60 so that an uneven surface on the first glue layer 50 is matched with an uneven surface of the first thermosetting material layer 60 to form a leveling layer.

In the forgoing operation S205, the uncured first thermosetting material layer 60 is heated to be cured, and the curing temperature of the first thermosetting material layer 60 can be reasonably set according to a specific material type of the first thermosetting material layer 60.

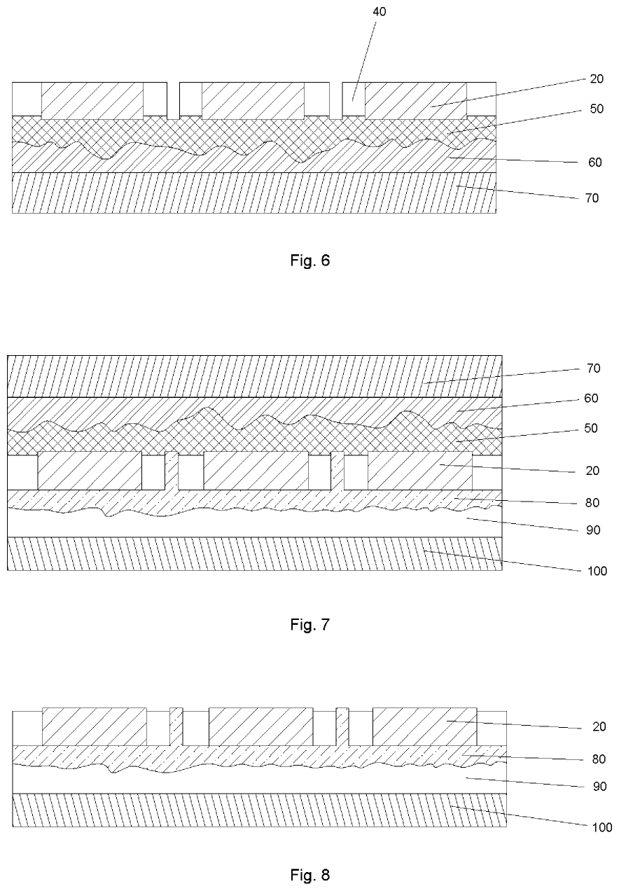

After operation S205 is completed, the one or multiple chips 20 can be lifted off from the growth substrate 10, so that the one or multiple chips 20 can be transferred to the first transient substrate 70, as shown in FIGS. 5 and 6.

In some embodiments, a laser lift-off process (LLO) is used to lift off the one or multiple chips 20 on the growth substrate 10, as shown in FIG. 5.

In the forgoing embodiment, the one or multiple chips 20 can be lifted off with lasers with wavelengths such as 266 nm, 355 nm, 532 nm, etc. To correspond to the pixels of the bonded display backplane, a selectively lift-off process can be used to lift off the one or multiple chips 20 corresponding to pixels of the display backplane.

In the forgoing embodiment, when the dead wall 30 and the soluble polymer layer 40 are provided between the adjacent chips 20, the soluble polymer layer 40 is lifted from the growth substrate 10, so that the one or multiple chips 20 and the soluble polymer layer 40 are transferred to the first transient substrate 70 at the same time. The forgoing soluble polymer layer 40 can be polyimide. Polyimide can be lifted off with a 308 nm wavelength laser. In the laser lift-off process, since the dead wall 30 cannot be lifted off, and remains on the growth substrate 10, a gap is formed between the adjacent chips 20.

After the operation of transferring the one or multiple chips 20 to the first transient substrate 70, the surface of the chip 20 away from the first transient substrate 70 is exposed. As shown in FIG. 6, the first transient substrate 70 has a portion of the one or multiple chips 20. The side of the first transient substrate 70 with the one or multiple chips is attached to the second transient substrate 100 via the second glue layer 80 to transfer the one or multiple chips 20 to the second transient substrate 100, as shown in FIGS. 7 and 8.

In some embodiments, the operation of attaching the side of the first transient substrate 70 with the one or multiple chips 20 to the second transient substrate 100 via the second glue layer 80 includes: coating the second glue layer 80 to the exposed side of the one or multiple chips 20 on the first transient substrate 70; providing the second transient substrate 100 having the surface covered with the uncured second thermosetting material layer 90, attaching the second thermosetting material layer 90 to the second glue layer 80; curing the second thermosetting material layer 90; lifting off the one or multiple chips 20 on the first transient substrate 70 to transfer the one or multiple chips 20 to the second transient substrate 100, As shown in FIG. 8.

In the forgoing embodiment, when the dead wall 30 is formed between adjacent chips 20 in the foregoing operations, after the one or multiple chips 20 are transferred to the first transient substrate 70, the dead wall 30 remains on the growth substrate 10, so that a gap is formed between the adjacent chips 20. At this time, part of the second glue layer 80 is filled in the gap to form a light-shielding structure for preventing colors between the adjacent chips from being mixed, as shown in FIG. 7 and FIG. 8.

In the forgoing embodiment, photolytic glue or pyrolytic glue may be coated on the growth substrate 10 to form the second glue layer 80 covering the chip 20. When the pyrolytic glue is used to form the first glue layer 50 covering the chip 20, the decomposition temperature of the forgoing pyrolytic glue is higher than the curing temperature of the second thermosetting material, so as to ensure that the pyrolytic glue will not decompose when the second thermosetting material is cured at a high temperature subsequently, thereby ensuring the adhesion to the one or multiple chips 20.

In the forgoing embodiment, the second thermosetting material used can also be one or more materials selected from phenolic resin, urea-formaldehyde resin, melamine resin, unsaturated polyester resin, epoxy resin, organic silicon resin, and polyurethane. However, the forgoing optional type is not limited. The person skilled in the art can reasonably select the second thermosetting material according to the prior art.

After the operation of transferring the chip 20 to the second transient substrate 100, the surface of the one or multiple chips 20 away from the second transient substrate 100 is exposed. The one or multiple chips 20 on the second transient substrate 100 can be bonded to the display backplane, to transfer the one or multiple chips 20 to the display backplane.

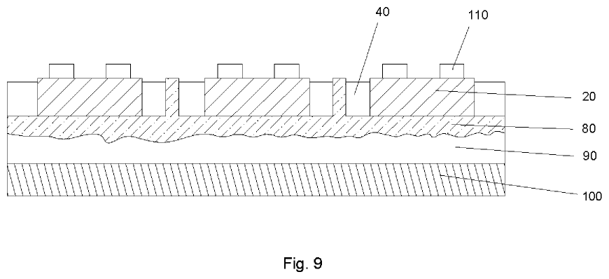

In some embodiments, after the operation of lifting off the one or multiple chips 20 on the first transient substrate 70, the operation of transferring the one or multiple chips 20 on the second transient substrate 100 to the display backplane includes: forming the electrode 110 on the exposed surface of each chip 20; providing the display backplane with a contact pad on a surface, as shown in FIG. 9; bonding the electrode of the chip 20 on the second transient substrate 100 to the contact pad; and lifting off the second transient substrate 100 to transfer the chip 20 to the display backplane.

In the forgoing embodiment, when the dead wall 30 and the soluble polymer layer 40 are arranged between the adjacent chips 20, after the operation of forming the electrode 110 on the exposed surface of each chip 20, the soluble polymer layer 40 is first removed. Then the electrode 110 is connected to the display backplane.

In some embodiments, the plurality of growth substrates 10 are provided. the chips 20 on the plurality of growth substrates 10 are transferred to the first transient substrate 70. The chips 20 is transferred to the second transient substrate 100. An electrode 110 is formed on the exposed surface of the chips 20.

Based on the same inventive concept, the application also provides a display device, including a display backplane and a chip transferred to the display backplane using the chip transfer method as described above.

It should be noted that the chip in this application is a Micro LED (a micro light emitting diode), or can be a nano-level LED.

It should be understood that the application of the application is not limited to the forgoing examples. For the person skilled in the art, improvements or changes can be made based on the forgoing description, and all these improvements and changes should fall within the protection scope of the appended claims of the application.

What is claimed is:

1. A chip transfer method, comprising the following operations of:
providing a growth substrate, forming one or multiple chips on a surface of the growth substrate, and covering a first glue layer on a surface, away from the growth substrate, of the one or multiple chips;
providing a first transient substrate covered with an uncured first thermosetting material layer; and attaching the first glue layer to the first thermosetting material layer; and
curing the first thermosetting material layer so that an uneven surface of the first glue layer is matched with an uneven surface of the first thermosetting material layer to form a leveling layer.

2. The chip transfer method according to claim 1, wherein the first glue layer is formed by pyrolytic glue, and a decomposition temperature of the pyrolytic glue is higher than a curing temperature of the first thermosetting material layer.

3. The chip transfer method according to claim 1, wherein the first glue layer is formed by photolytic glue.

4. The chip transfer method according to claim 1, wherein the material of the first thermosetting material layer is one or multiple materials selected from phenolic resin, urea-formaldehyde resin, melamine resin, unsaturated polyester resin, epoxy resin, organic silicon resin, and polyurethane.

5. The chip transfer method according to claim 1, wherein there are multiple chips which are arranged at intervals, and the operation of covering the first glue layer on the surface, away from the growth substrate, of the multiple chips comprises:
arranging a dead wall between adjacent chips, wherein a gap is provided between the chips and the dead wall;
forming a soluble polymer layer on the growth substrate corresponding to the gap;
coating the first glue layer on the growth substrate, wherein the first glue layer is configured to cover the surface of, away from the growth substrate, of the one or multiple chips.

6. The chip transfer method according to claim 5, wherein a height of the dead wall is the same as a height of the chips in a direction perpendicular to the growth substrate.

7. The chip transfer method according to claim 5, wherein a height of the soluble polymer layer is smaller than a height of the dead wall in a direction perpendicular to the growth substrate.

8. The chip transfer method according to claim 5, wherein the soluble polymer layer is a polyimide layer.

9. The chip transfer method according to claim 1, wherein after the operation of generating the leveling layer, the chip transfer method further comprises:
lifting off the one or multiple chips from the growth substrate to transfer the one or multiple chips to the first transient substrate;
attaching one side of the first transient substrate with the one or multiple chips to the second transient substrate via a second glue layer to transfer the one or multiple chips to the second transient substrate;
bonding the one or multiple chips on the second transient substrate to a display backplane to transfer the one or multiple chips to the display backplane.

10. The chip transfer method according to claim 9, wherein the operation of attaching one side of the first transient substrate with the one or multiple chips to the second transient substrate via the second glue layer comprises:
coating the second glue layer to an exposed side of the one or multiple chips on the first transient substrate;
providing the second transient substrate having a surface covered with an uncured second thermosetting material layer, attaching the second thermosetting material layer to the second glue layer, and curing the second thermosetting material layer;
lifting off the one or multiple chips on the first transient substrate to transfer the one or multiple chips to the second transient substrate.

11. The chip transfer method according to claim 10, wherein the second glue layer is formed by pyrolytic glue, and a decomposition temperature of the pyrolytic glue is higher than a curing temperature of the second thermosetting material layer.

12. The chip transfer method according to claim 10, wherein the material of the second thermosetting material layer is one or more materials selected from phenolic resin, urea-formaldehyde resin, melamine resin, unsaturated polyester resin, epoxy resin, organic silicon resin, and polyurethane.

13. The chip transfer method according to claim 9, wherein after the operation of lifting off the one or multiple chips on the first transient substrate, the operation of transferring the one or multiple chips on the second transient substrate to the display backplane comprises:
forming an electrode on an exposed surface of each chip;
providing the display backplane with a contact pad on a surface, and bonding the electrode of the chip on the second transient substrate to the contact pad;
lifting off the second transient substrate to transfer the chip to the display backplane.

14. A display device, comprising a display backplane and a chip located on the display backplane, wherein the chip is transferred to the display backplane by using a chip transfer method, wherein the chip transfer method comprises the following operations of:
providing a growth substrate, forming one or multiple chips on a surface of the growth substrate, and covering a first glue layer on a surface, away from the growth substrate, of the one or multiple chips;
providing a first transient substrate covered with an uncured first thermosetting material layer; and attaching the first glue layer to the first thermosetting material layer; and
curing the first thermosetting material layer so that an uneven surface of the first glue layer is matched with an uneven surface of the first thermosetting material layer to form a leveling layer.

15. The display device according to claim 14, wherein the first glue layer is formed by pyrolytic glue, and a decomposition temperature of the pyrolytic glue is higher than a curing temperature of the first thermosetting material layer.

16. The display device according to claim 14, wherein the first glue layer is formed by photolytic glue.

17. The display device according to claim 14, wherein the material of the first thermosetting material layer is selected from one or more of phenolic resin, urea-formaldehyde resin, melamine resin, unsaturated polyester resin, epoxy resin, organic silicon resin, and polyurethane.

18. The chip transfer method according to claim 1, wherein the operation of forming one or multiple chips on a surface of the growth substrate comprises:
completing a LED epitaxy film layer on the growth substrate, and cutting the LED epitaxy film layer to form a plurality of independent LED chips.

19. The chip transfer method according to claim 1, wherein the first transient substrate is the rigid substrate, and the rigid substrate comprises one of the following substrates: the glass plate, the quartz plate, and the sapphire.

20. The chip transfer method according to claim 9, wherein the operation of lifting off the one or multiple chips from the growth substrate comprises:
lifting off the one or more chips from the growth substrate by using a laser lift-off process.
